(19) United States
(12) Patent Application Publication
(10) Pub. No.: US 2004/0257162 A1
(43) Pub. Date: Dec. 23, 2004

(54) CHARGE PUMP FOR ELIMINATING DC MISMATCHES AT COMMON DRIAN NODES

(76) Inventor: Hadj L. Mokeddem, Sacramento, CA (US)

Correspondence Address: BUCKLEY, MASCHOFF, TALWALKAR LLC, 5 ELM STREET, NEW CANAAN, CT, 06840, US

(21) Appl. No.: 10/602,120

(22) Filed: Jun. 23, 2003

(51) Int. Cl. H03L 7/00

(52) U.S. Cl. 331/16

(57) ABSTRACT

A charge pump includes a first operational amplifier that maintains two sides of a PMOS/NMOS differential pair at the same voltage, and a second operational amplifier that prevents current imbalances for the source and sink of the PMOS/NMOS differential pair.

### BACKGROUND

In a known type of phase locked loop (PLL), a charge pump is coupled between a phase detector and a voltage controlled oscillator (VCO). However, CMOS charge pumps may exhibit DC mismatches, which may cause a static phase error in the PLL. The DC mismatches of CMOS charge pumps may also cause jitter in the PLL output.

In other charge pumps that are employed in PLLs, the switching speed may be limited.

### BRIEF DESCRIPTION OF THE DRAWINGS

FIG. 1 is a schematic circuit diagram of a charge pump according to some embodiments.

FIG. 2 is a block diagram of a charge pump according to some other embodiments.

FIG. 3 is a schematic circuit diagram of a discharging portion of the charge pump of FIG. 2.

FIG. 4 is a block diagram of an apparatus in which the charge pumps of FIG. 1 or FIG. 2 may be employed.

FIG. 5 is a block diagram of a serializer/deserializer that is part of the apparatus of FIG. 4.

FIG. 6 is a block diagram of a PLL that is part of the serializer/deserializer of FIG. 5 and that includes one of the charge pumps of FIG. 1 or FIG. 2.

### DETAILED DESCRIPTION

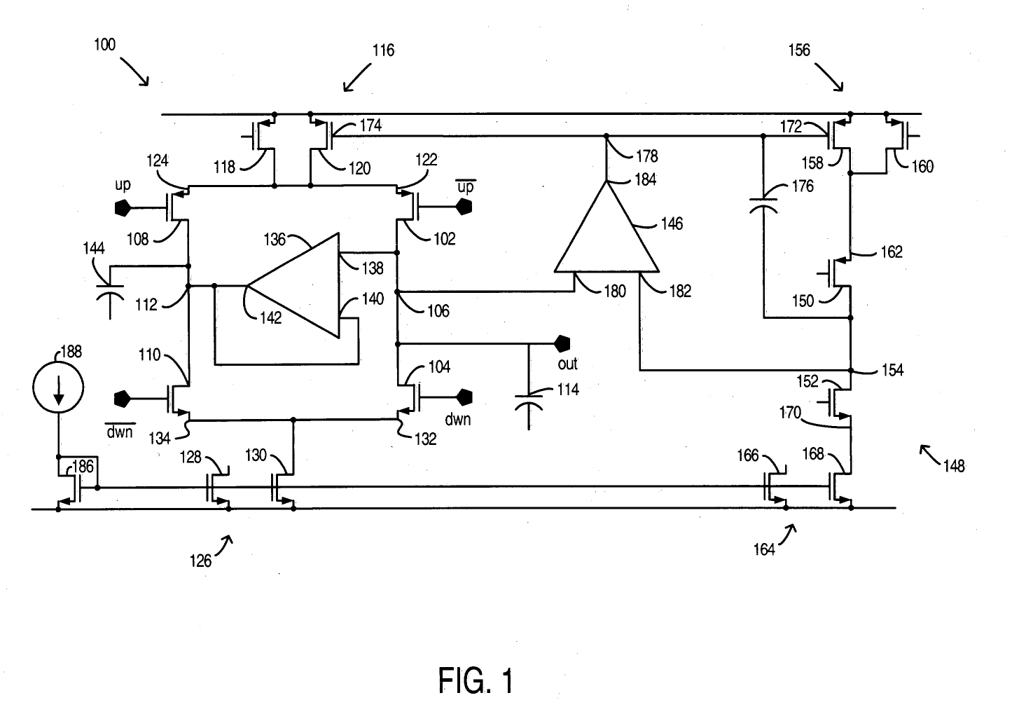

FIG. 1 is a schematic circuit diagram of a charge pump 100 according to some embodiments. The charge pump 100 includes a first input PMOS transistor 102 and a first input NMOS transistor 104 coupled to the first input PMOS transistor 102 via a first common drain node 106. The charge pump 100 also includes a second input PMOS transistor 108 and a second input NMOS transistor 110 coupled to the second input PMOS transistor via a second common drain node 112. Also included in the charge pump 100 is an output capacitor 114 coupled to the first common drain node 106.

The charge pump 100 further includes a first current source 116, formed of PMOS devices 118 and 120. The first current source 116 is coupled to the source terminal 122 of the first input PMOS transistor 102. The first current source 116 is also coupled to the source terminal 124 of the second input PMOS transistor 108.

Also included in the charge pump 100 is a second current source 126, formed of NMOS devices 128, 130. The second current source 126 is coupled to the source terminal 132 of the first input NMOS transistor 104. The second current source 126 is also coupled to the source terminal 134 of the second input NMOS transistor 110.

The charge pump 100 also includes a first operational amplifier 136. The first operational amplifier 136 has a first input (e.g., a non-inverting input) 138 that is coupled to the first common drain node 106. The first operational amplifier 136 also has a second input (e.g., an inverting input) 140 and an output 142, both of which are coupled to the second common drain node 112. A capacitor 144 is also coupled to the second common drain node 112 to stabilize the second common drain node 112.

The charge pump 100 further includes a second operational amplifier 146 and a reference circuit 148. The reference circuit 148 includes a PMOS transistor 150 and an NMOS transistor 152 coupled to the PMOS transistor 150 via a third common drain node 154. The gate terminals of the transistors 150 and 152 are coupled to constant DC voltages (not indicated in the drawing) to duplicate voltages seen by input transistors 102 and 104 when the input transistors are on. The reference circuit 148 also includes a PMOS current source 156 formed of PMOS devices 158, 160. The PMOS current source 156 is coupled to the source terminal 162 of the PMOS transistor 150.

The reference circuit 148 also includes an NMOS current source 164 formed of NMOS devices 166, 168. The NMOS current source 164 is coupled to the source terminal 170 of the NMOS transistor 152.

The devices 158, 160, 150, 152, 160, 168 of the reference circuit 148 are formed such that the reference circuit 148 is a replica of the circuit formed from the first current source 116, the first input PMOS transistor 102, the first input NMOS transistor 104 and the second current source 126.

The gate terminal 172 of the PMOS device 158 is coupled to the gate terminal 174 of the PMOS device 120. A capacitor 176 is coupled between the third common drain node 154 and the common node 178 of the gate terminals 172, 174 of the PMOS devices 158, 120. (Some or all of the capacitors 114, 176, 144 may be provided off-chip.)

The second operational amplifier 146 has a first input (e.g., an inverting input) 180 that is coupled to the first common drain node 106. The second operational amplifier 146 also has a second input (e.g., a non-inverting input) 182 that is coupled to the third common drain node 154. The second operational amplifier 146 also has an output 184 that is coupled to the gate terminals 174, 172 of the PMOS devices 120, 158 via the common node 178.

An NMOS device 186 provides biasing for the devices 128, 130, 166, 168. The NMOS device 186 is coupled to a current source 188, which may be provided in a circuit block (not otherwise shown) that may be separate from the circuitry shown in FIG. 1.

In operation, when the first input PMOS transistor 102 is on, the second input PMOS transistor 108 is off, and vice versa. When the first input NMOS transistor 104 is on, the second input NMOS transistor 110 is off, and vice versa. When the first input PMOS transistor 102 is on, the first input NMOS transistor 104 is off, and vice versa.

At a time when the first input PMOS transistor 102 is on (the first input NMOS transistor 104 and the second input PMOS transistor 108 then being off, and the second input NMOS transistor 110 on), the first current source 116 charges the output capacitor 114. At a time when the first input NMOS transistor 104 is on (the first input PMOS transistor 102 and the second input NMOS transistor 110 then being off, and the second input PMOS transistor 108 on), the second current source 126 discharges the output capacitor 114.

The first operational amplifier 136, with its inputs 138, 140 respectively coupled to the first common drain node 106 and to the second common drain node 112, may substantially eliminate DC mismatches due to differences in voltage at the common drain nodes 106, 112 (which are the differential outputs of the charge pump 100). Potential mismatches between the currents of the first current source 116 and the second current source 126 may be substantially eliminated by the second operational amplifier 146, which has its inputs 180, 182 respectively coupled to the first common drain node 106 and the third common drain node 154 of the reference circuit 148. The output 178 of the second operational amplifier 146 either increases or decreases the current of the first current source 116 to keep the respective currents of the first current source 116 and the second current source 126 the same.

With mismatches eliminated or minimized, the performance of the charge pump 100 may be such as to reduce the possibility of a static phase error and/or output jitter in a PLL (not shown in FIG. 1) of which the charge pump 100 is a part.

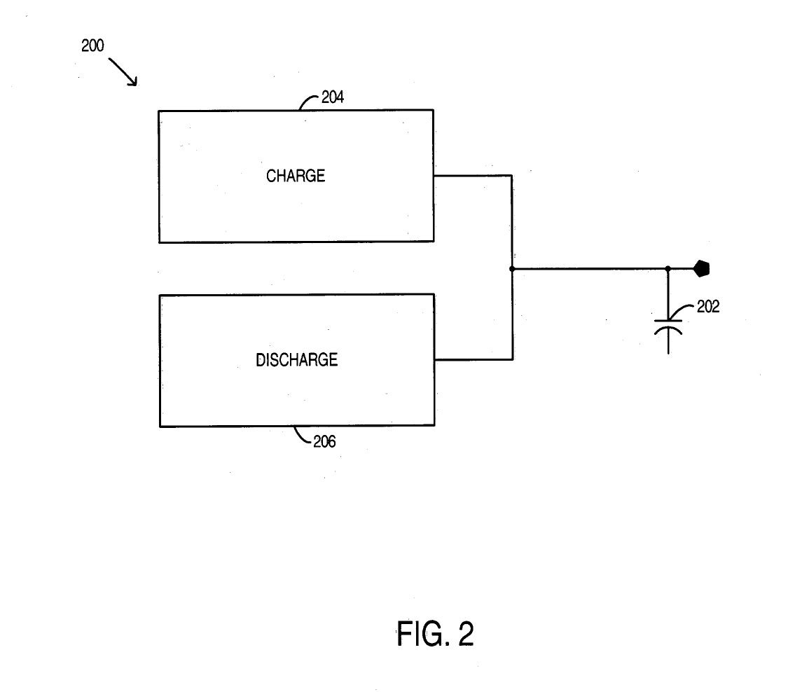

FIG. 2 is a block diagram of a charge pump 200 according to some other embodiments. The charge pump 200 includes an output capacitor 202, a charging portion 204 which selectively charges the output capacitor 202, and a discharging portion 206 which selectively discharges the output capacitor 202.

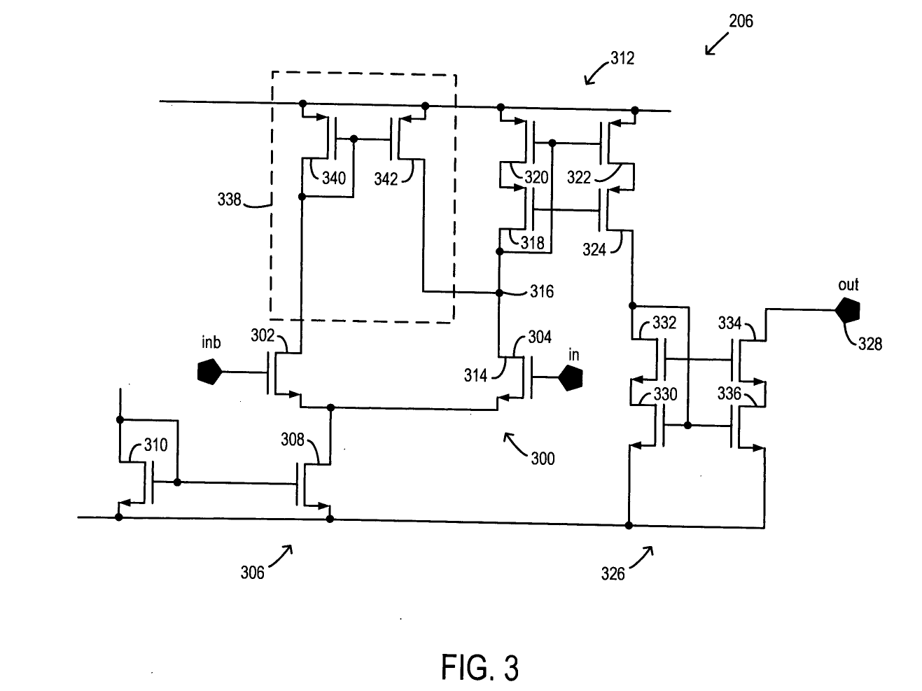

FIG. 3 is a schematic circuit diagram of the discharging portion 206 shown in FIG. 2.

The discharging portion 206 includes an input differential pair 300 (NMOS transistors 302, 304). The input differential pair 300 is biased by a current source 306 (NMOS device 308, biased in turn by NMOS device 310).

The discharging portion 206 further includes a first current mirror 312 coupled to the drain terminal 314 of the transistor 304 via a common drain node 316. The first current mirror 312 is formed of PMOS devices 318, 320, 322, 324.

The discharging portion 206 also includes a second current mirror 326 coupled to the first current mirror 312. The second current mirror 326 is also coupled to an output node 328 of the charge pump 200 (FIG. 2), to selectively discharge the output terminal 328. (It will be understood that the output node 328 is coupled to the output capacitor 202 (FIG. 2).) The second current mirror 326 is formed of NMOS devices 330, 332, 334, 336.

Also included in the discharging portion 206 is a third current mirror 338 coupled as a load to the transistor 302. The third current mirror 338 is formed of PMOS devices 340, 342 and is also coupled to the common drain node 316 to selectively pull up the common drain node.

In operation of the discharging portion 206, when the transistor 304 is on, the transistor 302 is off, and vice versa. In response to certain input signals applied to the charge pump 200 (FIG. 2), the transistor 304 (FIG. 3) is turned on, which causes the first current mirror 312 to conduct current, in turn causing the second current mirror 326 to conduct current to discharge the output node 328.

When the transistor 304 is on, the common drain node 316 is at a lower voltage than the supply voltage. When the transistor 304 is switched off, the first current mirror 312 has very little current to pull up the common drain node 316. Moreover, the smaller the difference in voltage between the common drain node and the supply, the less current there is in the first current mirror 312. However, the third current mirror 338 leverages on the current in the transistor 302 to provide current to rapidly pull up the common drain node 316.

In the absence of the third current source 338, the discharging portion 206 would fail to provide a sharp shut-off, thereby compromising high speed performance. However, with the third current source, the common drain node 316 is promptly pulled up to the supply voltage, so that the first and second current mirrors accurately follow the turning off of the transistor 304.

The topology of the charging portion 204 (FIG. 2) of the charge pump 200 may be congruent to the discharging side circuitry shown in FIG. 3. Accordingly, it is not necessary to describe the charging portion 204 in detail. With additional current sources (like the third current source 338) in the charging and discharging portions, a CMOS switching charge pump may be suitable for use in gigabit applications.

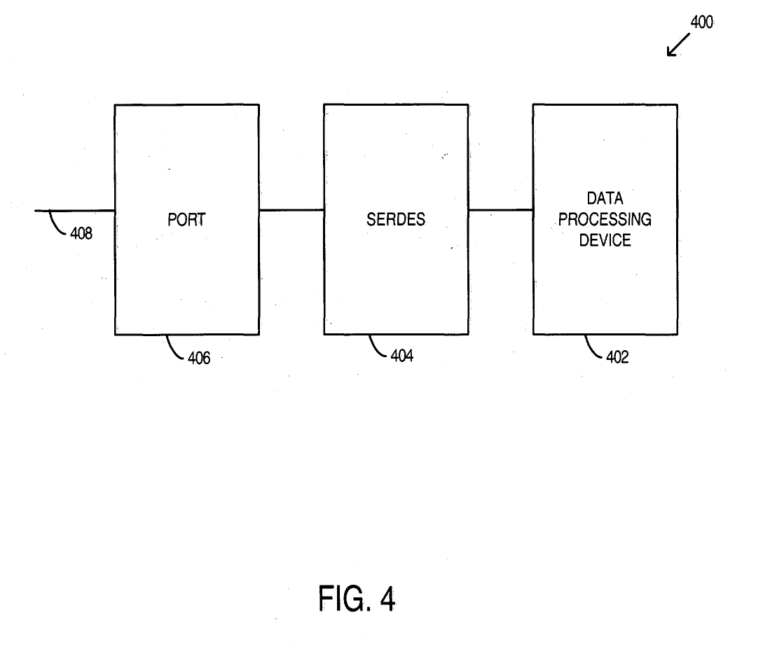

FIG. 4 is a block diagram of an apparatus 400 which may incorporate either of the types of charge pump described above. The apparatus 400 includes a data processing device 402 and a serializer/deserializer 404 coupled between the data processing device 402 and a communication port 406. The communication port 406, in turn, is coupled to a communication channel 408. Except for the serializer/deserializer 404, all of the components of the apparatus 400 may be conventional. For example, the data processing device 402 may be a conventional computer or storage system.

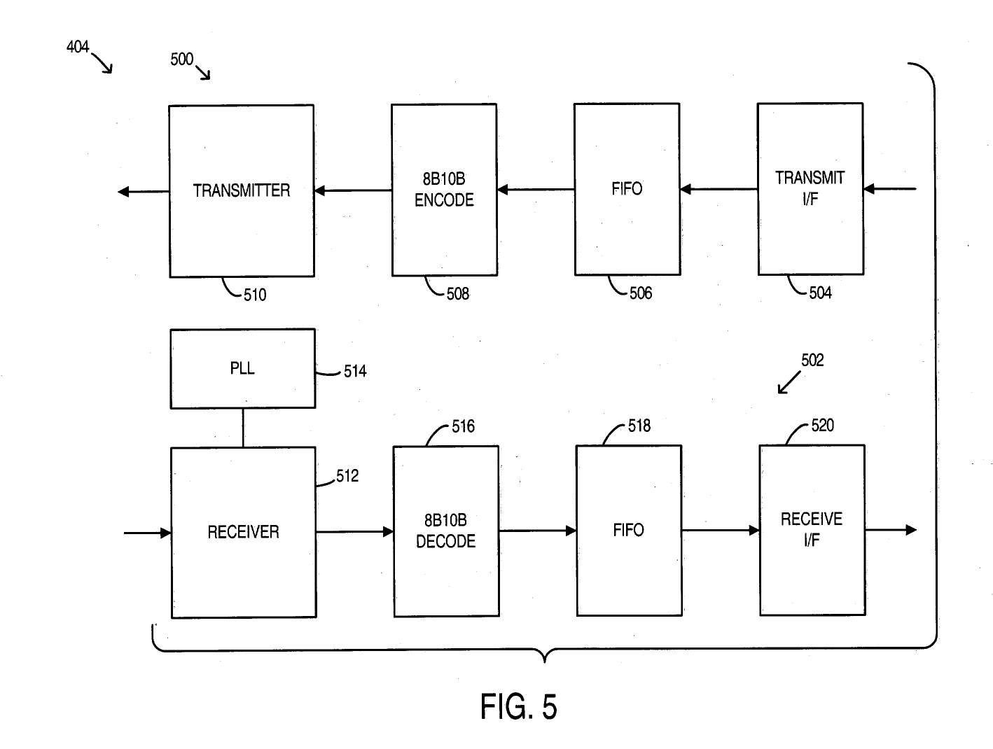

FIG. 5 is a simplified block diagram of the serializer/deserializer 404 shown in FIG. 4.

Referring to FIG. 5, the serializer/deserializer 404 includes a transmit path 500 and a receive path 502. The transmit path 500 includes a transmit interface 504 and a first in/first out (FIFO) memory 506 coupled to the transmit interface 504 to buffer outbound data words. Downstream from the FIFO memory 506 is an 8-bit-to-10-bit encoding block 508. Coupled to the downstream side of the 8-bit-to-10-bit encoding block 508 is a transmitter block 510 which outputs a serial bit stream on the communication channel 408 (FIG. 4).

The receive path 502 includes a receiver block 512, which receives an inbound serial bit stream, and a phase locked loop 514, which is associated with the receiver block 512 to recover the clock signal in the inbound bit stream. Coupled downstream from the receiver block 512 are a 10-bit-to-8-bit decoding block 516, and a receive-side FIFO memory 518, which buffers inbound data words. A receive interface 520 is coupled to the receive side FIFO memory 518.

Except for the phase locked loop 514, the serializer/deserializer 404 and all of its components may be entirely conventional.

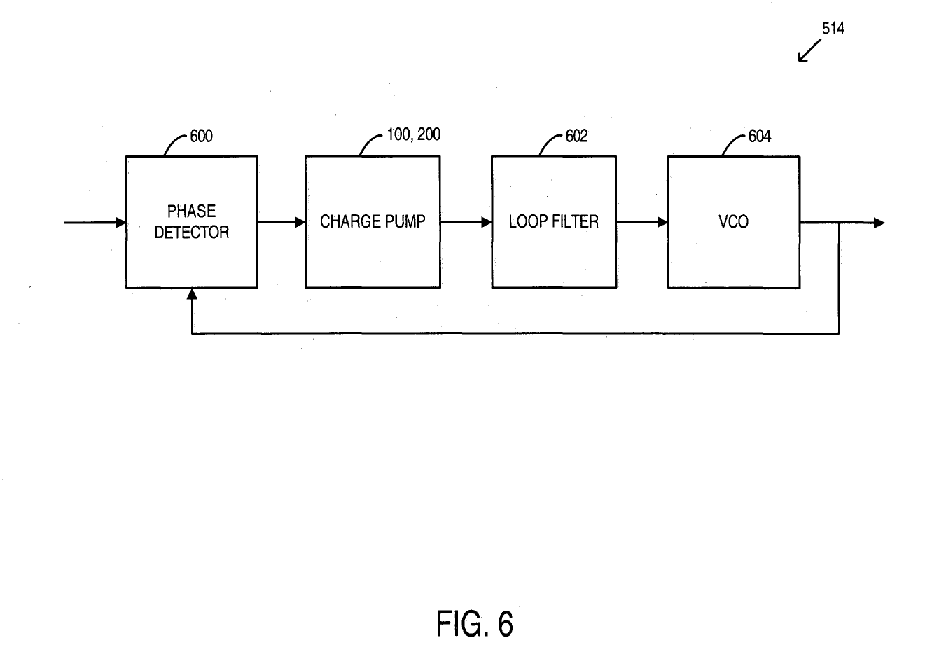

FIG. 6 is a block diagram of the phase locked loop 514 shown in FIG. 5.

The phase locked loop 514 includes a phase detector 600 which receives the input signal of the PLL 514 and which also receives a feedback signal which is described below. The phase detector 600 detects a difference in phase between the input signal and the feedback signal and provides an output based on the detected phase difference.

The PLL 514 further includes a charge pump, which is coupled to receive the output of the phase detector 600, and which may be like the charge pump 100 illustrated in FIG. 1 or the charge pump 200 described above with reference to FIGS. 2 and 3. The output of the charge pump 100 or 200 is filtered by a loop filter (low-pass filter) 602 and then drives a voltage controlled oscillator (VCO) 604. The signal output from the VCO 604 is the output of the PLL 514 and is also fed back to the phase detector 600.

Except for the charge pump 100 or 200, the PLL 514 and all of its components may be conventional.

While the charge pumps described herein are particularly suitable for use in a PLL that is used in a serializer/deserializer that recovers the clock component of an input serial data signal, the charge pumps described herein could also be part of PLLs used for other purposes. For example, a PLL which includes one of the charge pumps described herein may be used in an RF synthesizer or in a clock generator, such as a clock generator of a microprocessor.

As has been seen, in some embodiments a charge pump may include a first PMOS transistor, and a first NMOS transistor coupled to the first PMOS transistor via a first common drain node. The charge pump of these embodiments may also include a second PMOS transistor and a second NMOS transistor coupled to the second PMOS transistor via a second common drain node. The charge pump of these embodiments may further include a first current source coupled to respective source terminals of the first and second PMOS transistors, and a second current source coupled to respective source terminals of the first and second NMOS transistors. There may also be included in the charge pump of these embodiments a first operational amplifier having a first input coupled to the first common drain node and a second input coupled to the second common drain node. The charge pump of these embodiments may also include a reference circuit and a second operational amplifier. The second operational amplifier may have a first input coupled to the first common drain node and a second input coupled to the reference circuit.

With the operational amplifiers provided in the charge pumps of these embodiments, DC mismatches may be minimized or substantially eliminated. Consequently, there may be less chance of a static phase error or output jitter in a PLL which incorporates a charge pump of this type.

In some other embodiments, a charge pump may include an input differential pair including a first transistor and a second transistor. The charge pump of these other embodiments may also include a first current mirror coupled to a drain terminal of the second transistor via a common drain node. The charge pump of these other embodiments may further include a second current mirror coupled to the first current mirror. The second current mirror may also be coupled to an output terminal of the charge pump to selectively discharge the output terminal. There may also be included in the charge pump of these other embodiments a third current mirror that is coupled as a load to the first transistor. The third current mirror may also be coupled to the common drain node to selectively pull up the common drain node.

In the charge pump of these other embodiments, the third current mirror may function to quickly pull up the common drain node upon the second transistor being switched off. This may improve the high speed switching performance of the charge pump of these other embodiments, so that the charge pump of these other embodiments is suitable for use in PLLs for high speed applications, such as gigabit applications.

The several embodiments described herein are solely for the purpose of illustration. The various features described herein need not all be used together, and any one or more of those features may be incorporated in a single embodiment. Therefore, persons skilled in the art will recognize from this description that other embodiments may be practiced with various modifications and alterations.

1. A charge pump comprising:
a first PMOS transistor;
a first NMOS transistor coupled to the first PMOS transistor via a first common drain node;
a second PMOS transistor;
a second NMOS transistor coupled to the second PMOS transistor via a second common drain node;
a first current source coupled to respective source terminals of the first and second PMOS transistors;
a second current source coupled to respective source terminals of the first and second NMOS transistors;
a first operational amplifier having a first input coupled to the first common drain node, a second input coupled to the second common drain node and an output directly coupled to the second common drain node;
a reference circuit; and
a second operational amplifier having a first input directly coupled to the first common drain node and a second input coupled to the reference circuit.

2. The charge pump of claim 1, further comprising a capacitor coupled to the first common drain node.

3. The charge pump of claim 1, wherein the reference circuit includes:
a third PMOS transistor;
a third NMOS transistor coupled to the third PMOS transistor via a third common drain node;
a third current source coupled to a source terminal of the third PMOS transistor; and
a fourth current source coupled to a source terminal of the third NMOS transistor;
wherein the second input of the second operational amplifier is coupled to the third common drain node.

4. The charge pump of claim 1, wherein the first current source is a PMOS current source.

5. The charge pump of claim 1, wherein the second current source is an NMOS current source.

6. (Canceled)

7. The charge pump of claim 1, wherein an output of the second operational amplifier is directly coupled to a gate terminal of the first current source.

8. An apparatus comprising:
a communication port; and
a serializer/deserializer coupled to the communication port, the serializer/deserializer including a phase locked loop, the phase locked loop including a charge pump, the charge pump including:
a first PMOS transistor;
a first NMOS transistor coupled to the first PMOS transistor via a first common drain node;
a second PMOS transistor;
a second NMOS transistor coupled to the second PMOS transistor via a second common drain node;
a first current source coupled to respective source terminals of the first and second PMOS transistors;
a second current source coupled to respective source terminals of the first and second NMOS transistors;
a first operational amplifier having a first input coupled to the first common drain node and having a second input and an output both directly coupled to the second common drain node;
a reference circuit; and
a second operational amplifier having a first input directly coupled to the first common drain node, a second input coupled to the reference circuit, and an output coupled to a gate terminal of the first current source.

9. The apparatus of claim 8, wherein the charge pump further includes a capacitor coupled to the first common drain node.

10. The apparatus of claim 8, wherein the reference circuit includes:
a third PMOS transistor;
a third NMOS transistor coupled to the third PMOS transistor via a third common drain node;
a third current source coupled to a source terminal of the third PMOS transistor; and
a fourth current source coupled to a source terminal of the third NMOS transistor;
wherein the second input of the second operational amplifier is coupled to the third common drain node.

11. The apparatus of claim 8, wherein the first current source is a PMOS current source.

12. The apparatus of claim 8, wherein the second current source is an NMOS current source.

13-24. (Canceled)

25. A charge pump comprising:
an output terminal;
a first element to control charging of the output terminal;
a second element to control discharging of the output terminal and including a common node with the first element;
a reference circuit; and
an operational amplifier including a first input directly coupled to the output terminal and a second input directly coupled to the reference circuit.

26. The charge pump of claim 25, wherein the first element comprises a first transistive element and the second element comprises a second transistive element.

27. The charge pump of claim 26, wherein the first element comprises a PMOS transistor and the second element comprises an NMOS transistor.

28. The charge pump of claim 25, wherein the reference circuit includes:
a first transistive element;
a second transistive element coupled to the first transistive element;
a first current source coupled to the first transistive element; and
a second current source coupled to the second transistive element.

29. The charge pump of claim 28, wherein the first transistive element comprises a PMOS transistor and the second transistive element comprises an NMOS transistor.

30. The charge pump of claim 29, wherein:
the first and second transistive elements include a common drain node; and
the second input of the operational amplifier is coupled to the common drain node.

31. The charge pump of claim 25, further comprising:
a second output terminal; and
a second operational amplifier including a first input coupled to the common node and including a second input coupled to the second output terminal.

32. An apparatus comprising:
a communication port; and
a serializer/deserializer coupled to the communication port, the serializer/deserializer including a phase locked loop, the phase locked loop including a charge pump, the charge pump including:
an output terminal;
a first element to control charging of the output terminal;
a second element to control discharging of the output terminal and including a common node with the first element;
a reference circuit; and
an operational amplifier having a first input directly coupled to the output terminal and a second input coupled to the reference circuit.

33. The apparatus of claim 32, wherein the first element comprises a first transistive element and the second element comprises a second transistive element.

34. The apparatus of claim 33, wherein the first element comprises a PMOS transistor and the second element comprises an NMOS transistor.

35. The apparatus of claim 32, wherein the reference circuit includes:
a first transistive element;
a second transistive element coupled to the first transistive element;
a first current source coupled to the first transistive element; and
a second current source coupled to the second transistive element.

36. The apparatus of claim 35, wherein the first transistive element comprises a PMOS transistor and the second transistive element comprises an NMOS transistor.

37. The apparatus of claim 36, wherein:
the first and second transistive elements include a common drain node; and
the second input of the operational amplifier is coupled to the common drain node.

38. The apparatus of claim 32, wherein the charge pump further includes:
a second output terminal; and
a second operational amplifier including a first input coupled to the common node and include a second input coupled to the second output terminal.
